(19) United States
(12) Patent Application Publication
(10) Pub. No.: US 2025/0057029 A1
(43) Pub. Date: Feb. 13, 2025

(54) DISPLAY DEVICE AND METHOD FOR MANUFACTURING THE DISPLAY DEVICE

(71) Applicant: Samsung Display Co., LTD., Yongin-si (KR)

(72) Inventors: Je Won YOO, Yongin-si (KR); Dong Jo KIM, Yongin-si (KR); Hyun KIM, Yongin-si (KR); Seung Min LEE, Yongin-si (KR)

(21) Appl. No.: 18/646,215

(22) Filed: Apr. 25, 2024

(30) Foreign Application Priority Data
Aug. 9, 2023 (KR) 10-2023-0104289

(51) Int. Cl. H10K 77/10; H10K 59/12; H10K 71/00

(52) U.S. Cl. CPC H10K 77/111; H10K 59/1201; H10K 71/851

(57) ABSTRACT

There is provided a display device including a second substrate corresponding to a main area, a pad area, and a bending area between the main area and the pad area, a first substrate at the main area and at the pad area and beneath the second substrate, and a display element layer at the main area and above the second substrate, wherein the first substrate includes a first sub-substrate overlapped with the main area, and including a first surface adjacent the second substrate, a second surface opposite to the first surface, and a first side directed toward the bending area, and a second sub-substrate spaced apart from the first sub-substrate and overlapped with the pad area, wherein a first inclined angle formed by the second surface and the first side is an obtuse angle.

### CROSS-REFERENCE TO RELATED APPLICATION

The present application claims priority to, and the benefit of, Korean Patent Application No. 10-2023-0104289, filed on Aug. 9, 2023, in the Korean Intellectual Property Office, the entire disclosure of which is incorporated herein by reference.

### BACKGROUND

### 1. Field

The present disclosure relates to a display device, and to a method for manufacturing the display device.

### 2. Description of the Related Art

With the advancement of the information age, the demand for a display device for displaying an image has increased with various forms. The display device may be a flat panel display device, such as a liquid crystal display device, a field emission display device, and a light-emitting display device.

The display device includes a display area that displays an image, and a non-display area near the display area, for example, a non-display area surrounding the display area. Recently, to increase the immersion of the display area and increase an aesthetic sense of the display device, a width of the non-display area has been gradually reduced.

Meanwhile, in a manufacturing process of the display device, the display device may be formed by cutting a mother substrate along a plurality of display cells DPC formed in the mother substrate.

### SUMMARY

An aspect of the present disclosure provides a display device and a method for manufacturing the display device, in which etching byproducts generated during etching of a substrate and etching dispersion are reduced or minimized.

The aspects of the present disclosure are not limited to those mentioned above and additional aspects of the present disclosure, which are not mentioned herein, will be clearly understood by those skilled in the art from the following description of the present disclosure.

According to one or more embodiments of the disclosure, a display device includes a second substrate corresponding to a main area, a pad area, and a bending area between the main area and the pad area, a first substrate at the main area and at the pad area and beneath the second substrate, and a display element layer at the main area and above the second substrate, wherein the first substrate includes a first sub-substrate overlapped with the main area, and including a first surface adjacent the second substrate, a second surface opposite to the first surface, and a first side directed toward the bending area, and a second sub-substrate spaced apart from the first sub-substrate and overlapped with the pad area, wherein a first inclined angle formed by the second surface and the first side is an obtuse angle.

A second inclined angle formed by the first surface and the first side may be an acute angle.

The first surface and the second surface may extend from the first side.

A thickness of the first substrate may be about 200 μm.

The first substrate might not overlap the bending area.

The second sub-substrate may further include a third surface adjacent the second substrate, and a second side directed toward the bending area, wherein a second inclined angle formed by the third surface and the second side is an acute angle.

The first surface and the third surface may be spaced apart from each other, wherein the second inclined angle increases as the first interval increases.

The second inclined angle may be about 42° or more and about 88° or less.

The first sub-substrate may include an edge surface extending from the second surface while overlapping an end of the first substrate, wherein an inclined angle formed by the second surface and the edge surface is an obtuse angle.

The display device may further include a second side connecting the first surface with the first side, wherein an undercut is formed between the second substrate and the second side.

An inclined angle formed by the first surface and the second side may be an obtuse angle.

The first side and the second side may extend from one another, wherein the first surface and the second surface extend from the first side and the second side.

An inclined angle formed by the first side and the second side may be an acute angle.

The second substrate and the second side may form a third inclined angle outside the first sub-substrate, wherein the third inclined angle is inside the undercut, and is an acute angle.

The third inclined angle may be about 14° or more and about 31° or less.

A length of the undercut in a direction parallel with the second substrate may be greater than a height of the undercut in a direction substantially perpendicular to the second substrate.

According to one or more embodiments of the disclosure, a method for manufacturing a display device, the method including forming display cells on a second mother substrate that is on an upper surface of a first mother substrate, forming a cutting line on the first mother substrate and the second mother substrate by irradiating a laser along a boundary of edges of the display cells, forming a groove on a lower surface of the first mother substrate overlapping a bending area of the second mother substrate, reducing a thickness of the first mother substrate by spraying an etchant onto the lower surface of the first mother substrate without a mask, and substantially concurrently removing a portion of the first mother substrate that overlaps the bending area of the second mother substrate along the groove, and forming a second substrate and a first substrate by cutting the first mother substrate and the second mother substrate along the cutting line, wherein the second substrate includes a first sub-substrate and a second sub-substrate spaced apart from each other, wherein the first sub-substrate further includes a first side directed toward the second sub-substrate, a first inclined angle being formed by the first side and the first substrate, and wherein the first inclined angle corresponds to a depth of the groove.

The depth of the groove may be about 0.4 times to about 0.9 times of the thickness of the first mother substrate.

A size of the first inclined angle may increase as the depth of the groove increases.

The method may further include forming a second inclined angle outside the first sub-substrate by the first side and the first substrate, wherein a size of the second inclined angle increases as the depth of the groove increases.

In the display device and the method for manufacturing the display device according to one or more embodiments, etching byproducts generated during etching of a substrate may be suppressed to reduce or minimize etching dispersion of the substrate.

The aspects according to the embodiments of the present disclosure are not limited to those mentioned above and more various effects are included in the following description of the present disclosure.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating a display device according to one or more embodiments;

FIG. 2 is a plan view illustrating a display panel according to one or more embodiments;

FIG. 3 is a perspective view illustrating a display device according to one or more other embodiments;

FIG. 4 is a cross-sectional view illustrating a display device, which is taken along the line Y1-Y1′ of FIG. 1;

FIG. 5 is a cross-sectional view illustrating a state that the display device of FIG. 4 is bent;

FIG. 6 is an enlarged cross-sectional view illustrating an area ‘A’ of FIG. 4;

FIG. 7 is another cross-sectional view illustrating a display device, which is taken along the line Y1-Y1′ of FIG. 1;

FIG. 8 is an enlarged cross-sectional view illustrating an area ‘C’ of FIG. 7;

FIG. 9 is a flow chart illustrating a method for manufacturing a display device according to one or more embodiments;

FIGS. 10 to 15 are perspective views illustrating a method for manufacturing a display device according to one or more embodiments; and

FIGS. 16 to 28 are cross-sectional views and graphs illustrating a method for manufacturing a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

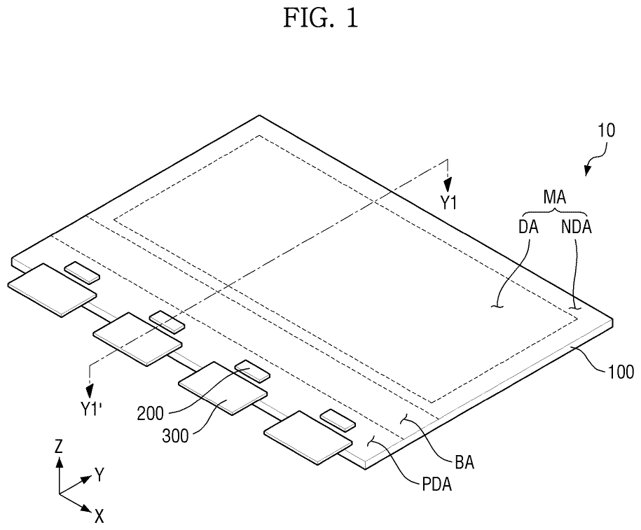

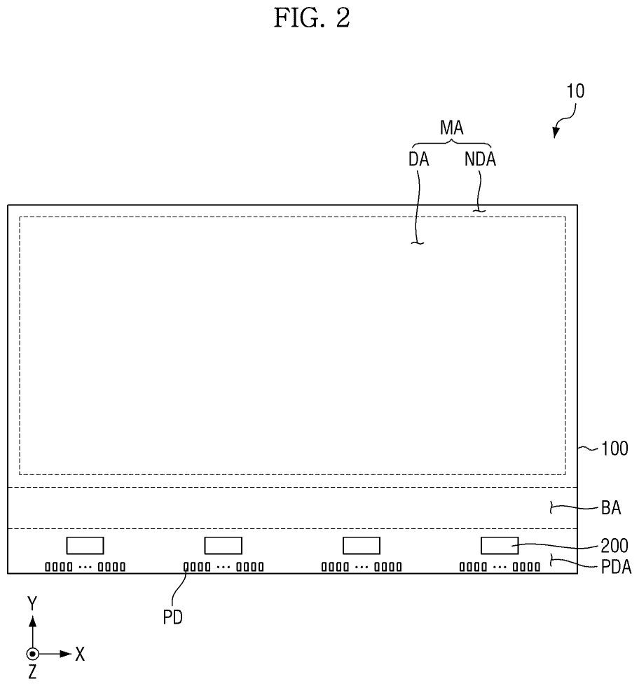

FIG. 1 is a perspective view illustrating a display device according to one or more embodiments. FIG. 2 is a plan view illustrating a display panel and a display driver according to one or more embodiments.

Referring to FIGS. 1 and 2, a display device 10 according to one or more embodiments is a device that displays a moving image or a still image, and may be used as a display screen of various products, such as a television, a laptop computer, a monitor, an advertising board and a device for Internet of things (IoT) as well as portable electronic devices, such as a mobile phone, a smart phone, a tablet personal computer (PC), a smart watch, a watch phone, a mobile communication terminal, an electronic diary, an electronic book, a portable multimedia player (PMP), a navigator and an ultra-mobile PC (UMPC).

The display device 10 according to one or more embodiments may be a light-emitting display device, such as an organic light-emitting display device using an organic light-emitting diode, a quantum dot light-emitting display device including a quantum dot light-emitting layer, an inorganic light-emitting display device including an inorganic semiconductor, and a micro or nano light-emitting display device using a micro or nano light-emitting diode (micro LED or nano LED). The following description will be based on that the display device 10 is an organic light-emitting display device, but the present disclosure is not limited thereto.

The display device 10 according to one or more embodiments may include a display panel 100, a display driver 200, and a circuit board 300.

The display panel 100 may be formed in a rectangular shaped plane having long sides in a first direction (X-axis direction), and short sides in a second direction (Y-axis direction) crossing the first direction (X-axis direction). A corner where the long side in the first direction (X-axis direction) and the short side in the second direction (Y-axis direction) meet may be formed at a right angle, or may be rounded to have a curvature. The plane shape of the display panel 100 is not limited to the rectangular shape, and may be formed in another polygonal shape, a circular shape, or an oval shape.

Herein, the first direction (X-axis direction) and the second direction (Y-axis direction) are horizontal directions and cross each other. For example, the first direction (X-axis direction) and the second direction (Y-axis direction) may be orthogonal to each other. Also, a third direction (Z-axis direction) may be a vertical direction crossing (e.g., orthogonal to) the first direction (X-axis direction) and the second direction (Y-axis direction). In the present disclosure, a direction indicated by an arrow in the first to third directions (X-axis direction, Y-axis direction, and Z-axis direction) may be referred to as one side, and its opposite direction may be referred to as the other side.

The display panel 100 may be formed to be flat, but is not limited thereto. For example, the display panel 100 may include a curved portion formed at left and right ends, and having a constant curvature or a variable curvature. In addition, the display panel 100 may be flexibly formed to be curved, bent, folded, or rolled.

The display panel 100 may include a main area MA, a bending area BA, and a pad area PDA. The main area MA may include a display area DA for displaying an image and a non-display area NDA located near the display area DA.

The display area DA may occupy a majority of the area of the display panel 100. The display area DA may be located at the center of the display panel 100. Pixels, each of which include a plurality of light emission areas, may be located in the display area DA to display an image.

The non-display area NDA may be adjacent to the display area DA. The non-display area NDA may be an outer area of the display area DA. The non-display area NDA may surround the display area DA (e.g., in plan view). The non-display area NDA may be an edge area of the display panel 100.

The bending area BA may be located between the main area MA and the pad area PDA in the second direction (Y-axis direction). The bending area BA may be an area bent toward a lower portion of the display panel 100. When the bending area BA is bent toward the lower portion of the display panel 100, a plurality of display drivers 200 and circuit boards 300 may be located at the lower portion of the display panel 100 in the third direction (Z-axis direction).

The pad area PDA may be a lower edge area of the display panel 100. The pad area PDA may be an area in which display pads PD connected to the circuit board 300 and to the display driver 200 are located. The display pads PD may be located at one side edge of the display panel 100. For example, the display pads PD may be located at a lower edge of the display panel 100.

The display drivers 200 may generate data voltages, power voltages, scan timing signals, and/or the like. The display drivers 200 may output the data voltages, the power voltages, the scan timing signals and/or the like. Each of the display drivers 200 may be attached to the non-display area NDA of the display panel 100 in a chip-on-glass (COG) scheme. In one or more other embodiments, each of the display drivers 200 may be attached to the circuit board 300 in a chip-on-plastic (COP) scheme.

The circuit boards 300 may be located on the display pads PD located at one side edge of the display panel 100. The circuit boards 300 may be attached to the display pads PD by using a conductive adhesive member, such as an anisotropic conductive film and an anisotropic conductive adhesive. Therefore, the circuit boards 300 may be electrically connected to signal lines of the display panel 100. The circuit boards 300 may be flexible printed circuit boards or flexible films, such as chip-on-films.

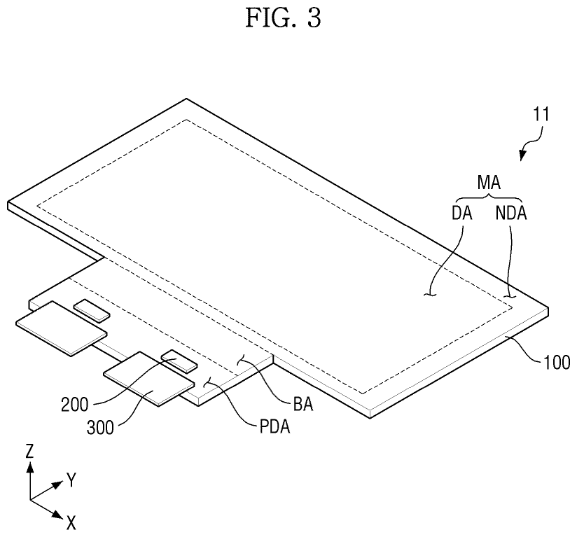

FIG. 3 is a perspective view illustrating a display device 11 according to one or more other embodiments.

Referring to FIG. 3, the shape of the display panel 100 described with reference to FIG. 3 may be different from that of the display panel 100 described with reference to FIG. 1. In detail, a length of the main area MA in the first direction (X-axis direction) may be longer than a length of the bending area BA and the pad area PDA in the first direction (X-axis direction). The bending area BA and the pad area PDA may have a shape protruded from one side of the main area MA. The shape of the display panel 100 is not limited to the shape shown in FIGS. 1 and 3, and various shapes may be applied thereto.

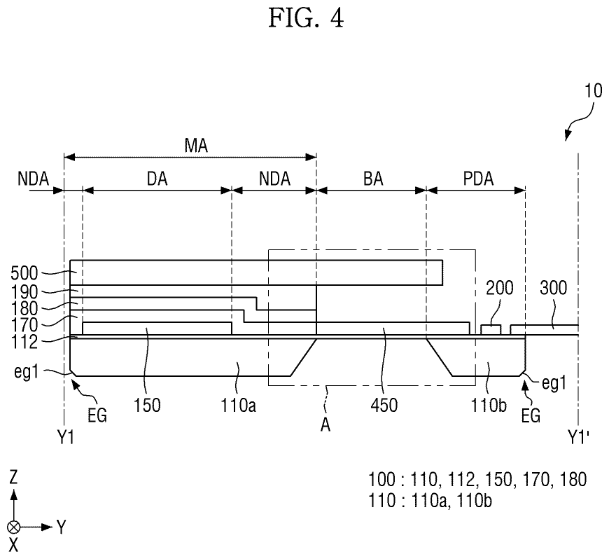

FIG. 4 is a cross-sectional view illustrating a display device 10, which is taken along the line Y1-Y1′ of FIG. 1.

Referring to FIG. 4, the display device 10 may include a display panel 100, a polarizing film 190, and a cover window 500, and the display panel 100 may include a first substrate 110, a second substrate 112, a display element layer 150, a thin film encapsulation layer 170, a touch sensor layer 180, and a bending protective layer 450.

The first substrate 110 may be made of a light-transmissive and rigid material. For example, the first substrate 110 may be a glass substrate or a plastic substrate. The first substrate 110 may be made of ultra-thin glass (UTG) having a thickness of about 200 μm or less.

In some embodiments, a portion of the first substrate 110, which overlaps the bending area BA, may be etched during a manufacturing process to ensure formation of the bending area BA and to support the second substrate 112. Therefore, the first substrate 110 may be divided into a first sub-substrate 110a and a second sub-substrate 110b. The first sub-substrate 110a and the second sub-substrate 110b may be spaced apart from each other while exposing the bending area BA. The first sub-substrate 110a may overlap the main area MA, and the second sub-substrate 110b may overlap the pad area PDA.

In some embodiments, the first substrate 110 may include an end EG at both ends in the second direction (Y-axis direction). The first substrate 110 may include an edge surface eg1 that overlaps the end EG, and that is on an opposite surface of one surface directed toward the second substrate 111. In detail, the second sub-substrate 110b may include an edge surface eg1 that overlaps the end EG at one side in the second direction (Y-axis direction), and the first sub-substrate 110a may include an edge surface eg1 that overlaps the end EG at the other side in the second direction (Y-axis direction). The edge surface eg1 may be an inclined surface. This may be caused as the manufacturing process of the display device 10 includes a laser process and an etching process, and will be described in detail later.

The second substrate 112 may be made of a polymer resin having a soft material. For example, the second substrate 112 may have a thickness of about 20 μm, approximately. The second substrate 112 may be formed of an organic material, such as an acryl resin, an epoxy resin, a phenolic resin, a polyamide resin, or a polyimide resin.

The display element layer 150 may be positioned on the second substrate 112, and may overlap the display area DA of the main area MA. The display element layer 150 is a layer for displaying an image, and may include a light-emitting layer for emitting light, and may include a plurality of signal lines.

The thin film encapsulation layer 170 may be located on the display element layer 150. The thin film encapsulation layer 170 may reduce or prevent oxygen or moisture from permeating into the display element layer 150. The thin film encapsulation layer 170 may include at least one inorganic film and one organic film. The organic film of the thin film encapsulation layer 170 may protect the display element layer 150 from particles, such as dust.

The touch sensor layer 180 may be located on the thin film encapsulation layer 170. The touch sensor layer 180 may include sensor electrodes. The touch sensor layer 180 may sense a touch of a user by using the sensor electrodes.

The polarizing film 190 may be located on the display panel 100 to reduce external light reflection. The polarizing film 190 may include a first base member, a linear polarizing plate, a phase delay film, such as a quarter-wave (N/4) plate, and a second base member. The first base member, the phase delay film, the linear polarizing plate, and the second base member of the polarizing film 190 may be sequentially stacked on the display panel 100.

The cover window 500 may be located on the polarizing film 190. The cover window 500 may be attached onto the polarizing film 190 by a transparent adhesive member, such as an optically clear adhesive (OCA).

The bending protective layer 450 may be positioned on the second substrate 112 by overlapping the bending area BA. The bending protective layer 450 may protect a lower structure, which overlaps the bending area BA, when the display panel 100 is bent.

The bending protective layer 450 may include a synthetic resin. For example, the bending protective layer 450 may include at least one of acrylonitrile butadiene styrene copolymer (ABS), urethane acrylate (UA), polyurethane (PU), polyethylene (PE), ethylene vinyl acetate (EVA), or polyvinyl chloride (PVC).

The display driver 200 and the circuit board 300 may be positioned on the second substrate 112 by overlapping the pad area PDA. The display driver 200 may be positioned between the bending protective layer 450 and the circuit board 300. The display driver 200 may be spaced apart from the bending protective layer 450 and the circuit board 300. One side of the circuit board 300 may be positioned so as not to overlap the second substrate 112, and the other side of the circuit board 300 may be positioned in contact with the second substrate 112.

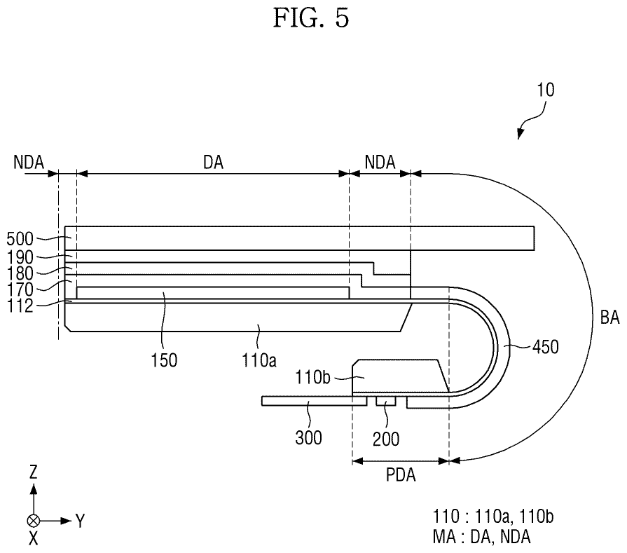

FIG. 5 is a cross-sectional view illustrating a state that the display device 10 of FIG. 4 is bent.

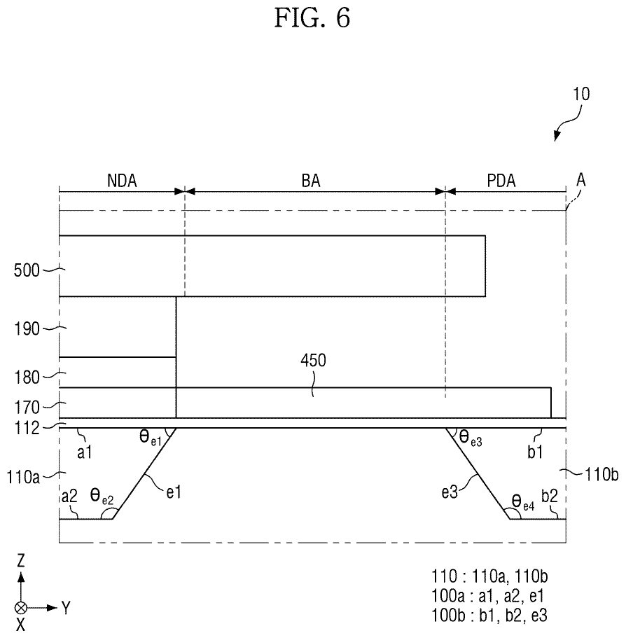

Referring to FIG. 5, a portion of the display device 10 may be bent by the bending area BA. When the display device 10 is bent, the pad area PDA of the display device 10 may overlap the main area MA in the third direction (Z-axis direction). Also, when the display device 10 is bent, the first sub-substrate 110a and the second sub-substrate 110b may overlap each other in the third direction (Z-axis direction). FIG. 6 is an enlarged cross-sectional view illustrating an area ‘A’ of FIG. 4.

Referring to FIG. 6, the first sub-substrate 110a may include an upper surface a1, a lower surface a2, and a first side e1. The upper surface a1 of the first sub-substrate 110a may be a surface that is in contact with the second substrate 112, and the lower surface a2 of the first sub-substrate 110a may be a surface opposite to the upper surface a1. The first side e1 of the first sub-substrate 110a may be positioned toward the bending area BA, and the upper surface a1 and the lower surface a2 may extend from the first side e1.

In some embodiments, the first side e1 included in the first sub-substrate 110a may be an inclined surface. In detail, a first inclined angle θe1 formed by the first side e1 and the upper surface a1 of the first sub-substrate 110a may be an acute angle, and a second inclined angle θe2 formed by the first side e1 and the lower surface a2 of the first sub-substrate 110a may be an obtuse angle.

In some embodiments, the second sub-substrate 110b of the display device 10 may include an upper surface b1 adjacent the second substrate 112, and a lower surface b2 opposite to the upper surface b1. A second side e3 of the second sub-substrate 110b may extend between the upper surface b1 and the lower surface b2 of the second sub-substrate 110b. The second side e3 of the second sub-substrate 110b may be an inclined surface. In detail, a first inclined angle θe3 formed by the second side e3 and the upper surface b1 of the second sub-substrate 110b may be an acute angle, and a second inclined angle θe4 formed by the second side e3 and the lower surface b2 of the second sub-substrate 110b may be an obtuse angle.

In some embodiments, a size of the first inclined angle θe1 formed by the first side e1 and the upper surface a1 of the first sub-substrate 110a, and a size of the first inclined angle θe3 formed by the second side e3 and the upper surface b1 of the second sub-substrate 110b, may be adjusted by a groove-forming process and an etching process in the manufacturing process of the display device 10. This will be described in detail later.

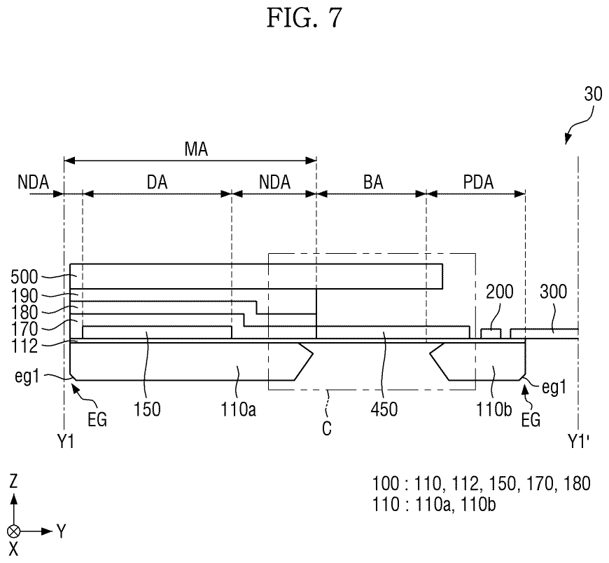

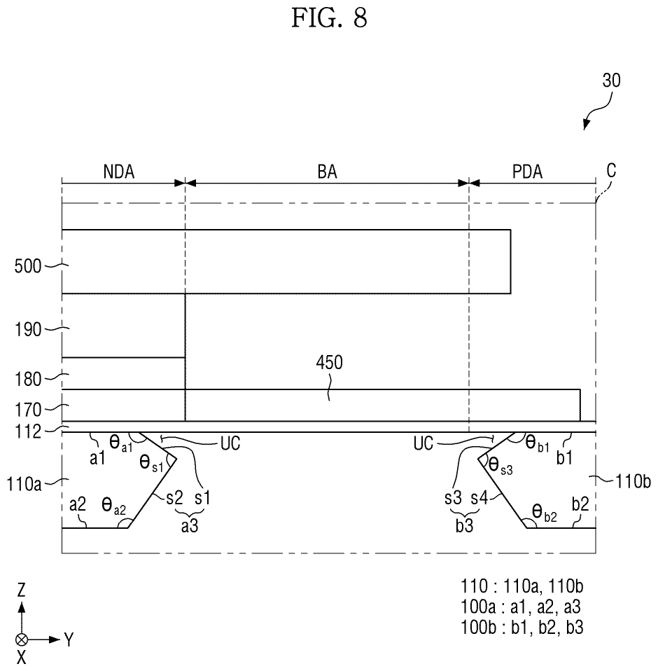

FIG. 7 is another cross-sectional view illustrating a display device 30, which is taken along the line Y1-Y1′ of FIG. 1. FIG. 8 is an enlarged cross-sectional view illustrating an area ‘C’ of FIG. 7.

Referring to FIGS. 7 and 8, a first sub-substrate 110a of the display device 30 may include an upper surface a1, a lower surface a2, and a side a3. The side a3 of the first sub-substrate 110a may be positioned toward the bending area BA, and the upper surface a1 and the lower surface a2 may extend from the side a3 of the display device 30.

The presently described one or more embodiments may be different from embodiments described above in that the side a3 of the first sub-substrate 110a includes a first inclined surface s1 connected to the upper surface a1, and a second inclined surface s2 connected to the lower surface a2. A first inclined angle θa1 formed by the upper surface a1 of the first sub-substrate 110a and the first inclined surface s1, and a second inclined angle θa2 formed by the lower surface a2 of the first sub-substrate 110a and the second inclined surface s2, may be obtuse angles.

In addition, the first inclined surface s1 and the second inclined surface s2 may extend toward each other, and a third inclined angle θs1 formed by the first inclined surface s1 and the second inclined surface s2 may be an acute angle, but the present disclosure is not limited thereto. The third inclined angle θs1 may include an obtuse angle depending on a shape of an undercut UC that will be described later.

In some embodiments, a second sub-substrate 110b of the display device 30 may include an upper surface b1, a lower surface b2, and a side b3 directed toward the bending area BA. The upper surface b1 of the second sub-substrate 110b may be a surface that is in contact with the second substrate 112, and the lower surface b2 of the second sub-substrate 110b may be a surface opposite to the upper surface b1. The side b3 of the second sub-substrate 110b may be positioned toward the bending area BA, and may be a surface connecting the upper surface b1 with the lower surface b2 of the second sub-substrate 110b.

The side b3 of the second sub-substrate 110b may include a first inclined surface s3 connected to the upper surface b1, and a second inclined surface s4 connected to the lower surface b2. A first inclined angle θb1 formed by the upper surface b1 of the second sub-substrate 110b and the first inclined surface s3, and a second inclined angle θb2 formed by the lower surface b2 of the second sub-substrate 110b and the second inclined surface s4, may be obtuse angles. In addition, the first inclined surface s3 and the second inclined surface s4 may extend toward each other, and a third inclined angle θs3 formed by the first inclined surface s3 and the second inclined surface s4 may be an acute angle, but the present disclosure is not limited thereto. The third inclined angle θs3 may include an obtuse angle depending on a shape of an undercut UC that will be described later.

As shown in FIG. 8, the undercut UC may be formed between the first inclined surface s1 of the first sub-substrate 110a and the second substrate 112, and between the first inclined surface s3 of the second sub-substrate 110b and the second substrate 112. The shape of the undercut UC may be changed by a groove-forming process and an etching process in the manufacturing process of the display device 30, as will be described in detail later.

The display device 30 described here, and the display device 10 included in one or more embodiments described above, are the same as each other in that they may be formed by an etching process in the manufacturing process, and in that a portion of the first substrate 110 is etched to be removed by overlapping the bending area BA. However, the shapes of the first sub-substrate 110a and the second sub-substrate 110b, which are directed toward the bending area BA, may be formed differently between the display device 30 included in the present embodiment and the display device 10 included in one or more embodiments depending on a type of an etchant and a variable factor of the etching process.

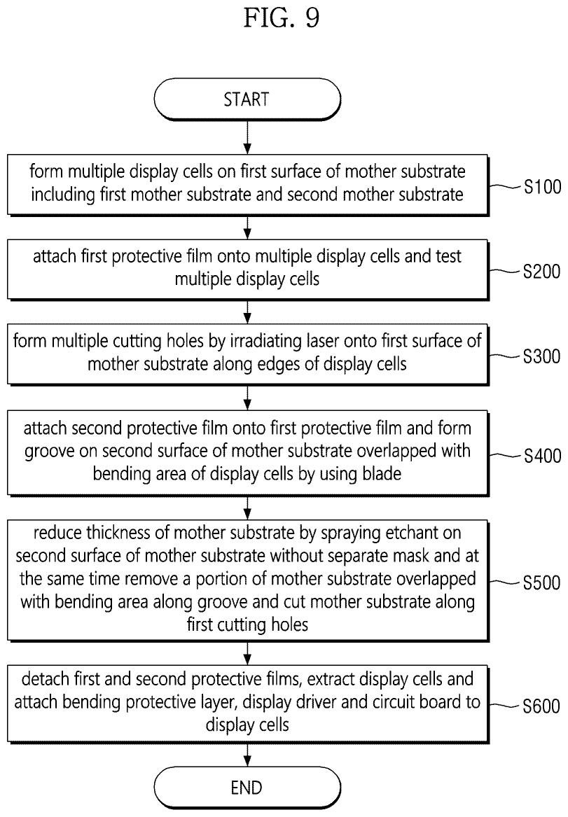

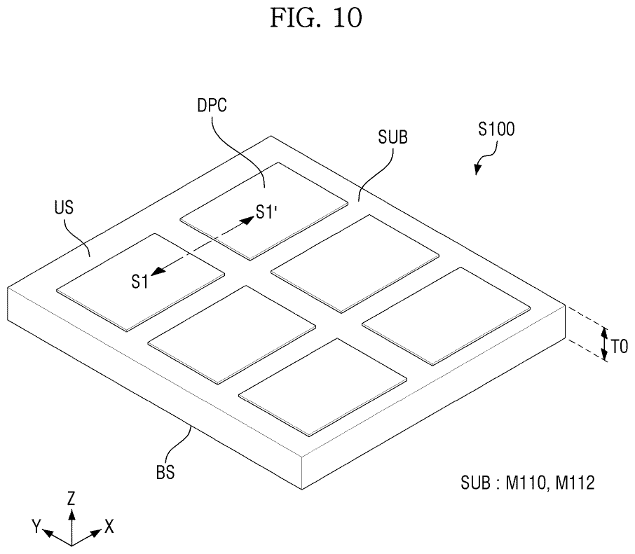

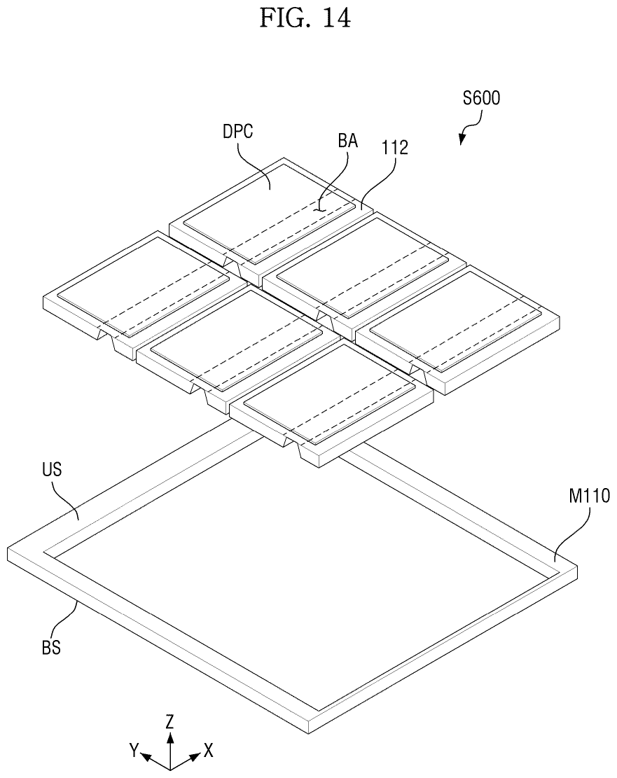

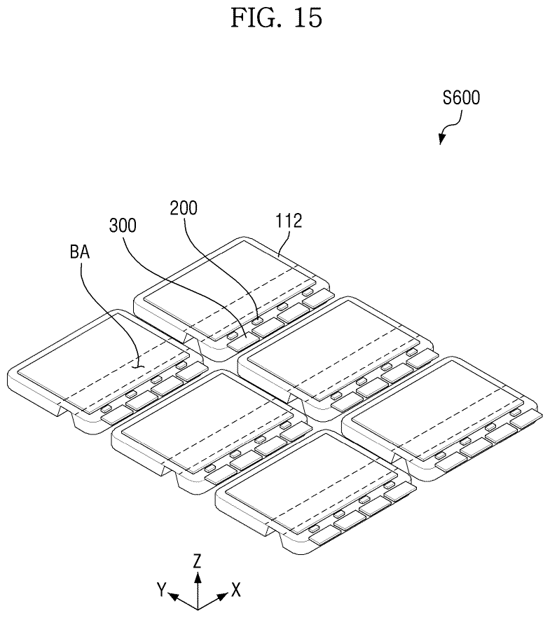

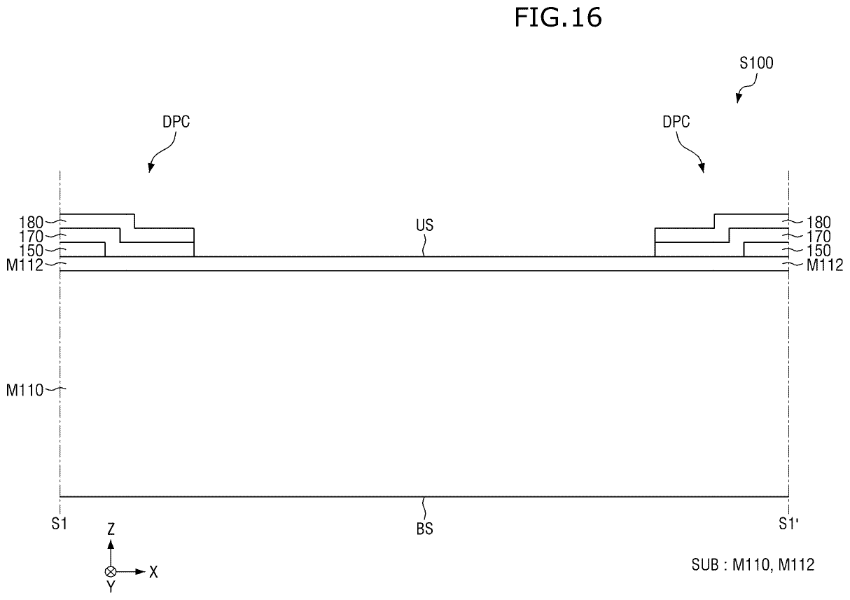

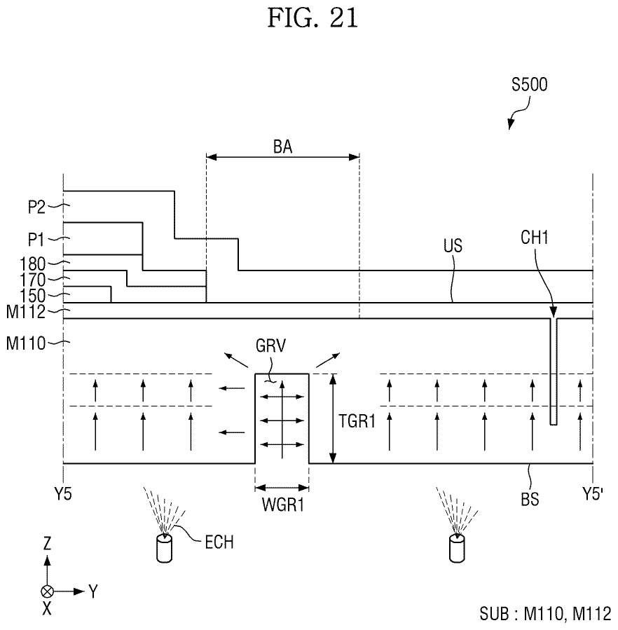

FIG. 9 is a flow chart illustrating a method for manufacturing a display device according to one or more embodiments. FIGS. 10 to 15 are perspective views illustrating a method for manufacturing a display device according to one or more embodiments. FIGS. 16 to 28 are cross-sectional views and graphs illustrating a method for manufacturing a display device according to one or more embodiments.

In the method for manufacturing a display device according to one or more embodiments, first, as shown in FIGS. 10 and 16, a plurality of display cells DPC are formed on a first surface US of a mother substrate SUB that includes a first mother substrate M110 and a second mother substrate M112 (S100 of FIG. 9). A first thickness T0 of the first mother substrate M110 may be about 500 μm.

Referring to FIGS. 10 and 16, the mother substrate SUB may include a first surface US and a second surface BS facing the first surface US. The display cell DPC positioned on the first surface US of the mother substrate SUB may include a first mother substrate M110, a second mother substrate M112, a display element layer 150, a thin film encapsulation layer 170, and a touch sensor layer 180.

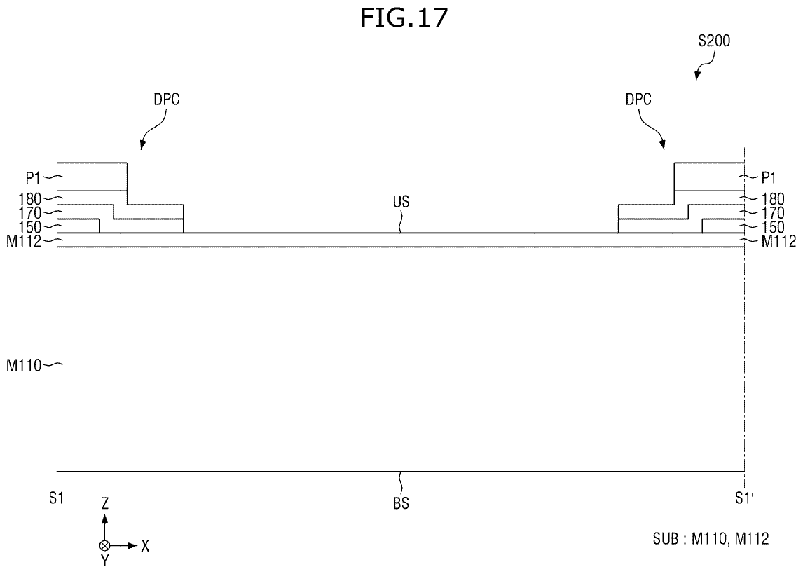

Second, as shown in FIG. 17, after a plurality of first protective films P1 are attached onto the plurality of display cells DPC, the plurality of display cells DPC are tested (S200 of FIG. 9).

A first protective film layer is attached to cover the first surface US of the mother substrate SUB located between the plurality of display cells DPC. Afterwards, when a portion of the first protective film layer located on the mother substrate SUB is removed, the plurality of first protective films P1 may be located on the plurality of display cells DPC, respectively. That is, the first protective film P1 shown in FIG. 17 may be a portion remaining after the first protective film layer is partially removed. Therefore, the plurality of first protective films P1 may be located on the plurality of display cells DPC, respectively. In other words, the plurality of first protective films P1 may correspond to the plurality of display cells DPC one-to-one. The plurality of first protective films P1 may be buffer films for protecting the plurality of display cells DPC from external impact. The plurality of first protective films P1 may be made of a transparent material.

Then, the plurality of display cells DPC are tested by using a test device. The test method may include connecting a probe to a plurality of test pads respectively provided in the plurality of display cells DPC, and then performing a lighting test for each of the plurality of display cells DPC.

As an example, when the lighting test is performed after the plurality of display cells DPC are separated from the mother substrate SUB by a cutting process, an additional process for removing the plurality of test pads after completing the lighting test is required. In contrast, in the case that the lighting test is performed on the mother substrate SUB, the plurality of test pads may be removed when the plurality of display cells DPC are separated from the mother substrate SUB through laser irradiation and etching later. Therefore, when the lighting test is performed on the mother substrate SUB, there is no need for a separate additional process for removing the plurality of test pads.

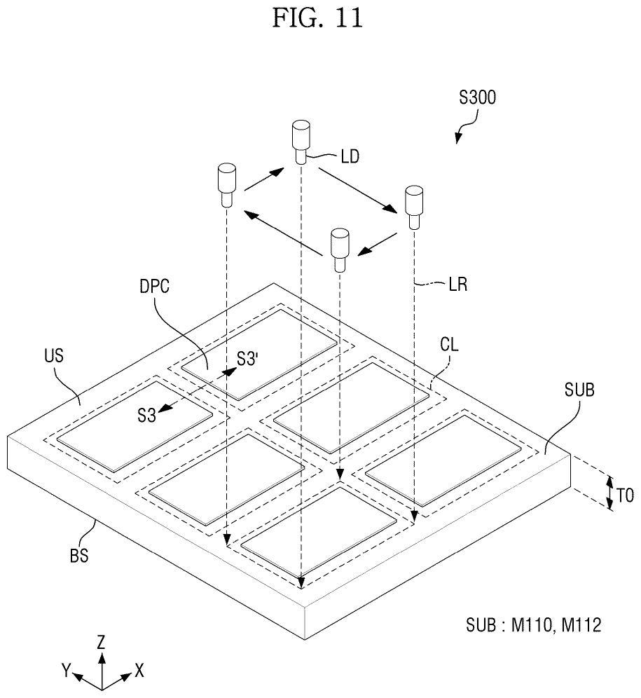

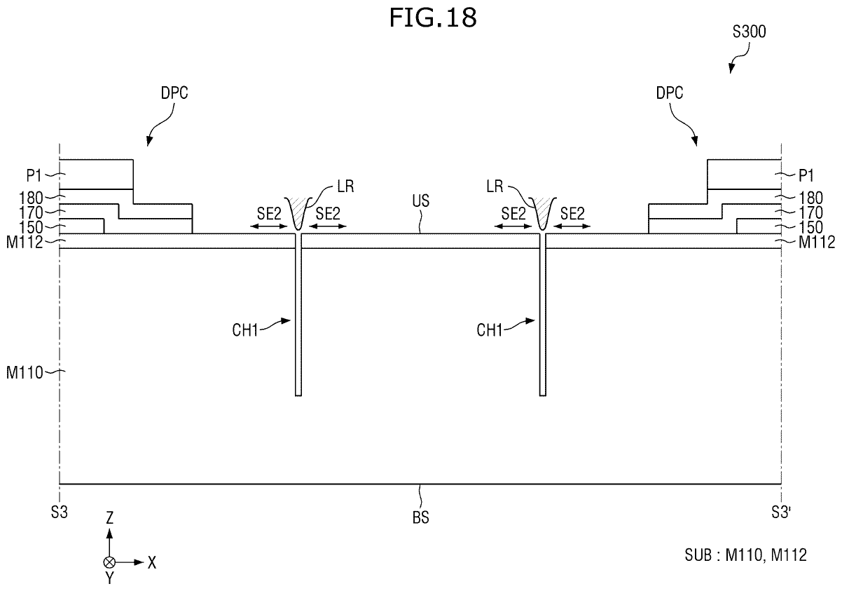

Third, referring to FIGS. 11 and 18, laser LR is irradiated onto the first surface US of the mother substrate SUB to form cutting lines CL located along the edges of the plurality of display cells DPC (S300 of FIG. 9).

Various lasers may be used as the laser LR according to one or more embodiments. In the example of the present disclosure, the laser LR is an infrared-based Bessel beam having a wavelength of about 1030 nm.

As shown in FIG. 18, the laser LR may be irradiated onto the first surface US of the mother substrate SUB, but the embodiments of the present disclosure are not limited thereto. The laser LR may be irradiated onto the second surface BS of the mother substrate SUB. A cut hole may be formed in a plurality of first laser irradiation areas CH1 to which the laser LR is irradiated. The cut hole may be specified as a throughhole, and may be formed as a plurality of cut holes.

The cutting line CL may be defined as a virtual line connecting the plurality of first laser irradiation areas CH1. The cutting line CL may be formed by irradiating the laser LR to form the plurality of first laser irradiation areas CH1 along the edges of the plurality of display cells DPC.

A unilateral tolerance SE2 of the laser LR may be within about 50 μm, and a bilateral tolerance of the laser LR may be within about 100 μm. The unilateral tolerance SE2 of the laser LR may be a cutting error in one direction (e.g., X-axis direction) when the plurality of first laser irradiation areas CH1 are formed by the laser LR.

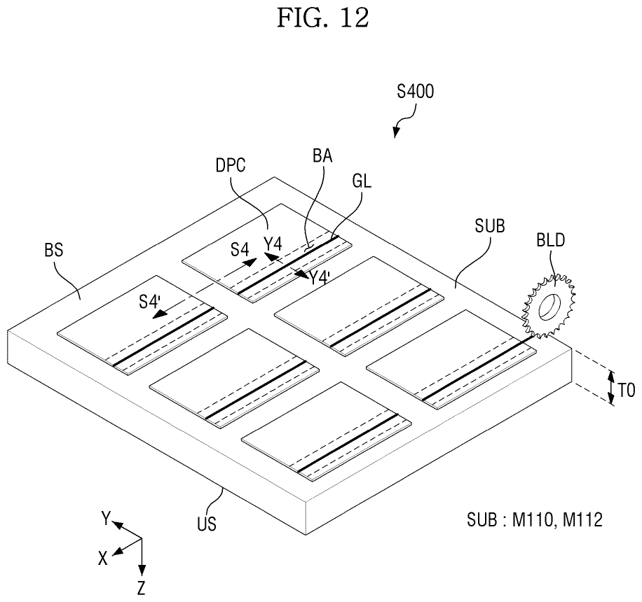

Fourth, referring to FIGS. 12, 19, and 20, a second protective film P2 is attached onto the plurality of first protective films P1, and a groove GRV is formed by using a blade BLD on the second surface BS of the mother substrate SUB by overlapping the bending area BA of the mother substrate SUB (S400 of FIG. 9).

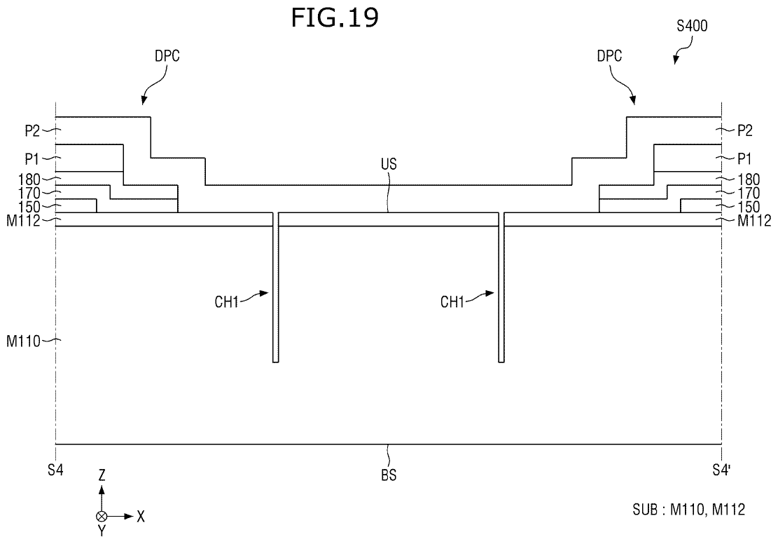

As shown in FIG. 19, the second protective film P2 may be attached onto the plurality of first protective films P1 and the exposed mother substrate SUB that is not covered by the plurality of first protective films P1. Therefore, the second protective film P2 may cover the first laser irradiation areas CH1. The second protective film P2 may be an acid-resistant film for protecting the plurality of display cells DPC from the etchant in the etching process of the mother substrate SUB, which will be performed in the next step.

Next, the groove GRV may be formed on the second surface BS of the mother substrate SUB. In detail, the groove GRV may be formed on the second surface BS by overlapping the bending area BA of the mother substrate SUB by using the blade BLD. The blade BLD may proceed from one side of the mother substrate SUB to the other side of the mother substrate SUB in the first direction (X-axis direction).

Therefore, a groove line GL may be formed on the second surface BS of the mother substrate SUB. The groove line GL may be formed by connecting a plurality of grooves GRV.

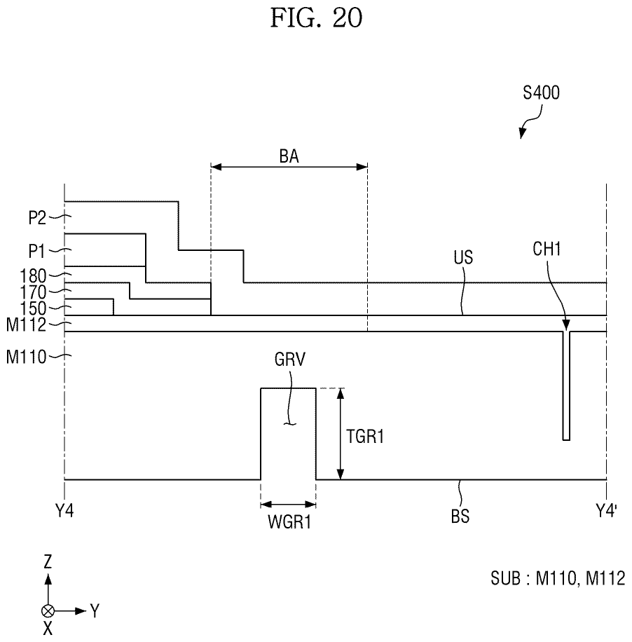

As shown in FIG. 20, the groove GRV may include a depth TGR1 and a width WGR1. For example, the depth TGR1 of the groove GRV may be about 0.4 times or more and about 0.9 times or less of the first thickness T0 of the first mother substrate M110. For example, when the first thickness T0 of the first mother substrate M110 is about 500 μm, the depth TGR1 of the groove GRV may be adjusted in the range of about 200 μm to about 450 μm. The width WGR1 of the groove GRV may be in the range of about 900 μm to about 920 μm.

A cross-sectional shape of the groove GRV is shown as being rectangular in the drawing, but is not limited thereto. For example, the cross-sectional shape of the groove GRV may be a polygon, such as a triangle or a trapezoid, or may include a curve, such as a ‘U’ shape.

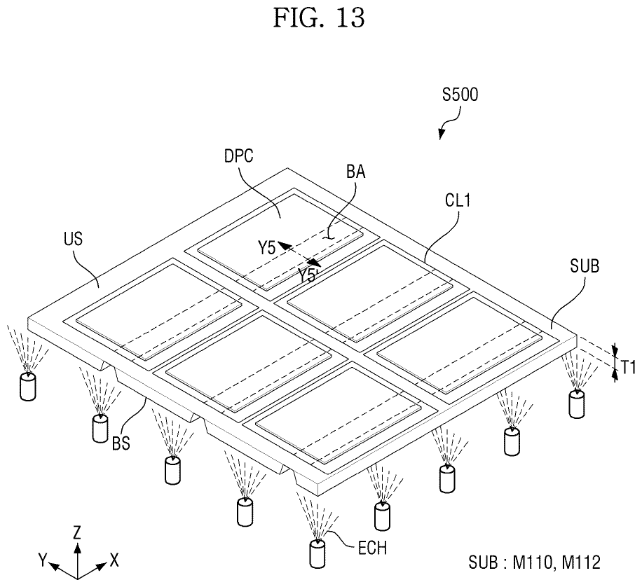

Fifth, referring to FIGS. 13, 14, 21, 22, 23, and 24, the etchant may be sprayed onto the second surface BS of the mother substrate SUB without a separate mask to reduce the thickness of the first mother substrate M110, and to concurrently remove a portion of the first mother substrate M110 overlapped with the bending area BA. In addition, the mother substrate may be cut along the plurality of first laser irradiation areas CH1 (S500 in FIG. 9).

As shown in FIGS. 13, 21, and 22, because the first mother substrate M110 is etched without a separate mask in the etching process, an isotropic etching process in which all areas of the second surface BS of the mother substrate SUB are substantially uniformly etched may be performed. Therefore, the mother substrate SUB may be reduced from the first thickness T0 to a second thickness T1.

However, when the etchant is sprayed onto the second surface BS of the mother substrate SUB, an etch rate of an area in which the first laser irradiation area CH1 is formed may be higher than an etch rate of the other first mother substrate M110 to which the laser is not irradiated. That is, anisotropic etching may be performed in which an etch rate in the area where the first laser irradiation area CH1 is formed is faster than an etch rate in an area where the first laser irradiation area CH1 is not formed. Therefore, as the etchant is permeated into the first laser irradiation area CH1, the mother substrate M110 may be separated along the cutting line CL, whereby each of the plurality of display cells DPC may be separated from the mother substrate SUB.

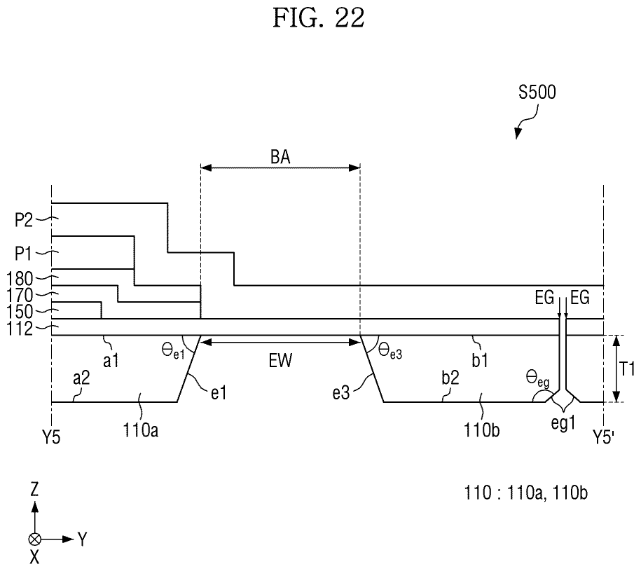

Therefore, as shown in FIG. 22, the first mother substrate M110 may be the first substrate 110, and the second mother substrate M112 may be the second substrate 112. That is, the first laser irradiation area CH1 may be the end EG of the first substrate 110 and the second substrate 112.

The first substrate 110 separated from the first mother substrate M110 may include an edge surface eg1 overlapped with the end EG of the first substrate 110. The edge surface eg1 may be a result obtained as an etch rate of a portion including the first laser irradiation area CH1 is higher than an etch rate of the other first mother substrate M110. In other words, as the edge surface eg1 is included in the end EG of the first substrate 110, it is noted that the display device 10 or 30 includes a laser irradiation process in the manufacturing process.

The edge surface eg1 may be formed on one side of the lower surface a2 or b2 of the first substrate 110 by overlapping the end EG of the first substrate 110, and an inclined angle θeg formed by the lower surface a2 or b2 of the first substrate 110 and the edge surface eg1 may be an obtuse angle.

Referring back to FIGS. 13, 21, and 22, an etch rate of a portion where a groove GRV is physically formed on the second surface BS of the mother substrate SUB may be higher than an etch rate of the second surface BS of another mother substrate SUB in which the groove GRV is not formed. In other words, anisotropic etching may be performed in which an etch rate in the area where the groove GRV is formed is faster than an etch rate in the area where the groove GRV is not formed. Therefore, the first mother substrate M110 overlapped with the bending area BA of the mother substrate SUB may be etched and removed, and the first mother substrate M110 of the other area may remain by being etched at the second thickness T1.

Therefore, as shown in FIG. 22, the first substrate 110 may include a first sub-substrate 110a and a second sub-substrate 110b, which are spaced apart from each other with the bending area BA interposed therebetween. The first sub-substrate 110a may include an upper surface a1 of the first sub-substrate 110a in a direction toward the second substrate 112, and the second sub-substrate 110b may include an upper surface b1 of the second sub-substrate 110b in a direction toward the second substrate 112. The upper surface a1 of the first sub-substrate 110a and the upper surface b1 of the second sub-substrate 110b may be spaced apart from each other as much as a first interval EW.

In addition, the first sub-substrate 110a and the second sub-substrate 110b may respectively include a first side e1 and a second side e3 toward the bending area BA. The first side e1 and the second side e3 may be inclined surfaces. In detail, the second substrate 112 and the first side e1 of the first sub-substrate 110a may form a first inclined angle θe1, and the second substrate 112 and the second side e3 of the second sub-substrate 110b may form a first inclined angle θe3. The first inclined angle θe1 included in the first sub-substrate 110a and the first inclined angle θe3 included in the second sub-substrate 110b may be acute angles.

In some embodiments, the first interval EW, and sizes of the first inclined angle θe1 included in the first sub-substrate 110a and of the first inclined angle θe3 included in the second sub-substrate 110b, may be adjusted depending on the depth TGR1 of the groove GRV in the groove formation process.

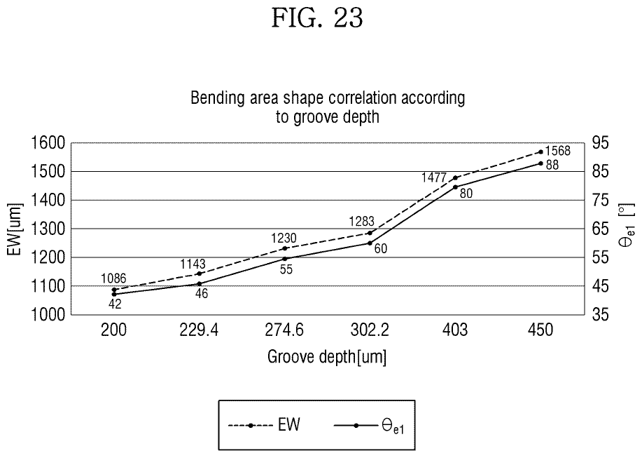

FIG. 23 is a graph illustrating a correlation of the first interval EW and the depth TGR1 of the groove GRV, and the inclined angles θe1 or θe2 and the depth TGR1 of the groove GRV.

The X-axis of the graph represents the depth TGR1 of the groove GRV. The depth TGR1 of the groove GRV shown in the X-axis is a value designated for convenience of description, and is not limited thereto. That is, the depth TGR1 of the groove GRV may include a range of 200 μm to 450 μm. The Y-axis of the graph, which is shown as ‘EW [μm]’, may represent the first interval EW, and the Y-axis of the graph, which is shown as ‘θe1[°],’ may represent the first inclined angle θe1. The width WGR1 of the groove GRV may be substantially uniformly maintained.

As shown in the graph, as the depth TGR1 of the groove GRV increases, the first interval EW and the first inclined angle θe1 may increase. In detail, when the depth TGR1 of the groove GRV increases within the range of about 200 μm to about 450 μm, the first interval EW may increase within the range of about 1086 μm to about 1568 μm, and when the depth TGR1 of the groove GRV increases within the range of about 200 μm to about 450 μm, the first inclined angle θe1 may increase in the range of about 42° to about 88°.

In some embodiments, the first interval EW and the first inclined angle θe1 may be factors that affect each other, and not independent factors.

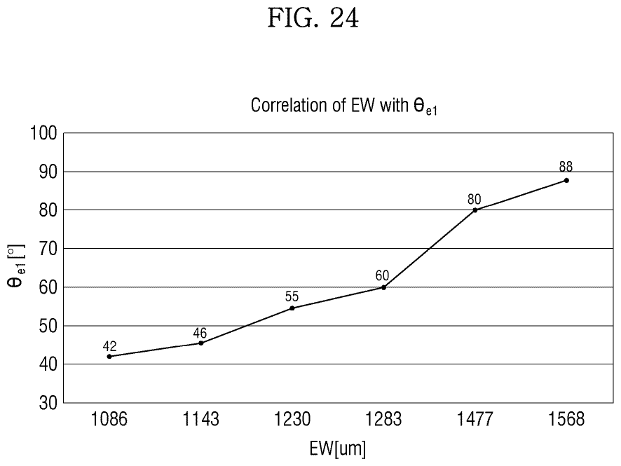

FIG. 24 is a graph illustrating correlation between the first interval EW and the first inclined angle θe1 when the width WGR1 of the groove GRV is substantially uniformly maintained, and when the depth TGR1 of the groove GRV increases within the range of about 200 μm to about 450 μm.

As shown in the graph, it is noted that the first inclined angle θe1 increases as the first interval EW increases. In one or more embodiments, the first inclined angle θe3 included in the second sub-substrate 110b may have a range that is less than or greater than the first inclined angle θe1 included in the first sub-substrate 110a (e.g., as much as about 1°), and the first inclined angle θe3 may increase as the depth TGR1 of the groove GRV increases.

Therefore, even though the width WGR1 of the groove GRV has the same value during the manufacturing process of the display device 10, the first interval EW, and the sizes of the first inclined angle θe1 included in the first sub-substrate 110a and of the first inclined angle θe3 included in the second sub-substrate 110b, may be adjusted by adjusting the depth TGR1 of the groove GRV. That is, the shape of the first substrate 110 may be adjusted.

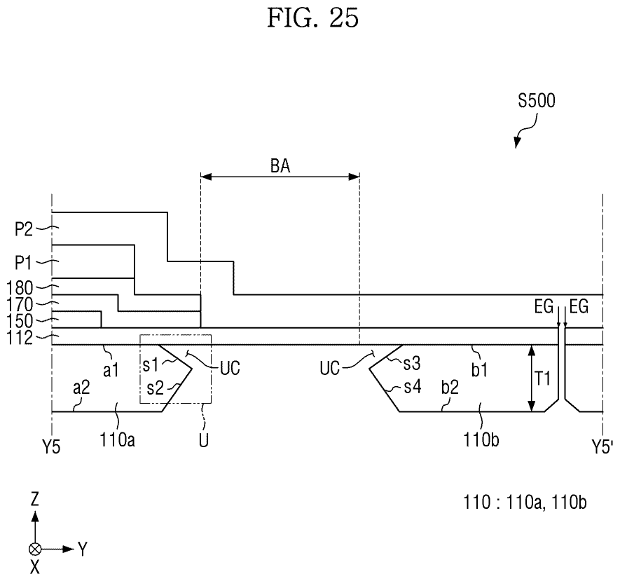

Referring to FIGS. 25 to 28, the first substrate 110 of the display device 30 may form an undercut UC in a direction toward the second substrate 112. Therefore, the first sub-substrate 110a may include a first inclined surface s1 and a second inclined surface s2 toward the bending area BA, and the second sub-substrate 110b may include a first inclined surface s3 and a second inclined surface s4 toward the bending area BA. The presently described one or more embodiments may include a shape that is different from that of one or more embodiments depending on the type of the etchant, an etching process condition and/or the like.

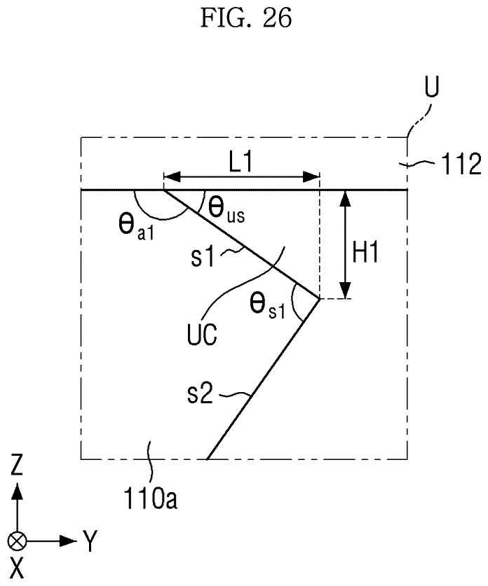

Referring to FIG. 26, the third inclined angle θs1 formed by the first inclined surface s1 and the second inclined surface s2 of the first sub-substrate 110a may be an acute angle, and the first inclined angle θa1 formed by the upper surface a1 of the first sub-substrate 110a and the first inclined surface s1 may be an obtuse angle. The other repeated description will be omitted.

The undercut UC formed between the first sub-substrate 110a and the second substrate 112 may include an undercut length L1, an undercut depth H1, and an undercut inclined angle θus. The undercut length L1, the undercut depth H1, and the undercut inclined angle θus may be adjusted in accordance with the depth TGR1 of the groove GRV in the manufacturing process.

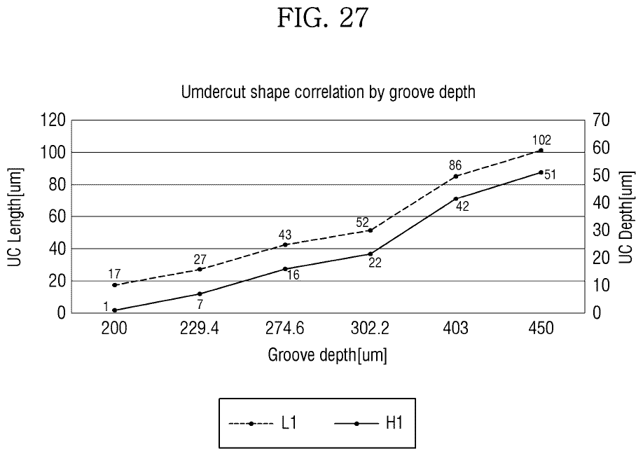

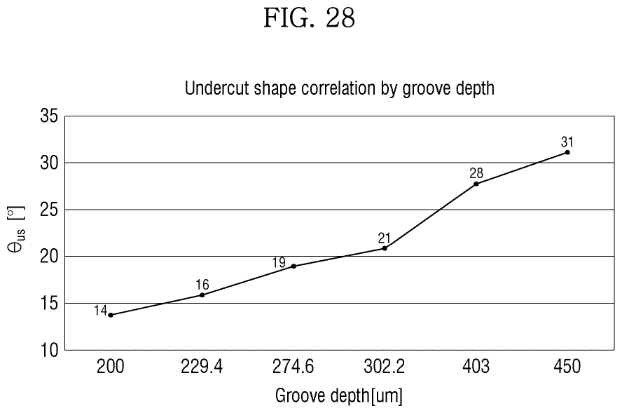

FIGS. 27 and 28 are graphs illustrating a correlation between the depth TGR1 of the groove GRV and the shape of the undercut UC. FIG. 27 is a graph illustrating a correlation of the depth TGR1 of the groove GRV and the undercut length L1 and the undercut depth H1, and FIG. 28 is a graph illustrating a correlation between the depth TGR1 of the groove GRV and the undercut inclined angle θus.

Referring to FIG. 27, the X-axis of the graph represents the depth TGR1 of the groove GRV. The depth TGR1 of the groove GRV shown in the X-axis is a value designated for convenience of description, and is not limited thereto. That is, the depth TGR1 of the groove GRV may include a range of about 200 μm to about 450 μm. The Y-axis of the graph may represent an undercut length L1 and an undercut depth H1. In the graph, the width WGR1 of the groove GRV may be substantially uniformly maintained.

As shown in the graph of FIG. 27, as the value of the depth TGR1 of the groove GRV increases, the undercut length L1 and the undercut depth H1 may increase. In detail, when the depth TGR1 of the groove GRV increases within the range of about 200 μm to about 450 μm, the undercut length L1 may increase within the range of about 17 μm to about 102 μm, and the undercut depth H1 may increase within the range of about 1 μm to about 51 μm.

Referring to FIG. 28, the X-axis of the graph represents the depth TGR1 of the groove GRV, and the Y-axis represents the undercut inclined angle θus. In the graph, the width WGR1 of the groove GRV may be substantially uniformly maintained.

As shown in the graph of FIG. 28, as the value of the depth TGR1 of the groove GRV increases, the undercut inclined angle θus may increase. In detail, when the depth TGR1 of the groove GRV increases within the range of about 200 μm to about 450 μm, the undercut inclined angle θus may increase within the range of about 14° to about 31°.

The undercut length L1, the undercut depth H1, and the undercut inclined angle θus may be factors that affect one another, and not independent factors. In detail, the undercut inclined angle θus may increase as the undercut length L1 and the undercut depth H1 increase. Therefore, even though the width WGR1 of the groove GRV has the same value, the undercut length L1, the undercut depth H1, and the size of the undercut inclined angle θus may be adjusted by adjusting the depth TGR1 of the groove GRV.

For convenience of description, the undercut UC formed between the second substrate 112 and the first sub-substrate 110a is shown, but the undercut UC formed between the second substrate 112 and the second sub-substrate 110b may also have the same shape and characteristics as those of the shown undercut UC.

Sixth, referring to FIGS. 4, 7, and 15, after the etching process is completed, the second protective film P2 may be detached, and the display driver 200 and the circuit board 300 may be attached to each of the plurality of display cells DPC. In addition, after the first protective film P1 is detached, the bending protective layer 450, the polarizing film 190, and the cover window 500 are attached (S600 of FIG. 9).

As described above, the physical groove GRV is formed on the first substrate 110 by overlapping the bending area BA before the etching process, whereby the amount of etching of the first substrate 110 may be reduced or minimized, and whereby generation of etching byproducts may be suppressed. Therefore, a defect caused by the etching byproducts may be avoided, and etching dispersion of the display device may be substantially uniform. In addition, the depth TGR1 of the aforementioned groove GRV may be adjusted so that the shape of the first substrate 110 may be variously adjusted, whereby manufacturing process efficiency of the display device may increase.

Features of various embodiments of the disclosure may be combined partially or totally. As will be clearly appreciated by those skilled in the art, technically various interactions and operations are possible. Also, various embodiments can be practiced individually or in combination.

In concluding the detailed description, those skilled in the art will appreciate that many variations and modifications can be made to the described embodiments without substantially departing from the aspects of the present disclosure. Therefore, the disclosed embodiments of the present disclosure are used in a generic and descriptive sense and not for purposes of limitation.

What is claimed is:

1. A display device comprising:
a second substrate corresponding to a main area, a pad area, and a bending area between the main area and the pad area;
a first substrate at the main area and at the pad area and beneath the second substrate; and
a display element layer at the main area and above the second substrate,
wherein the first substrate comprises:
a first sub-substrate overlapped with the main area, and comprising a first surface adjacent the second substrate, a second surface opposite to the first surface, and a first side directed toward the bending area; and
a second sub-substrate spaced apart from the first sub-substrate and overlapped with the pad area,
wherein a first inclined angle formed by the second surface and the first side is an obtuse angle.

2. The display device of claim 1, wherein a second inclined angle formed by the first surface and the first side is an acute angle.

3. The display device of claim 2, wherein the first surface and the second surface extend from the first side.

4. The display device of claim 3, wherein a thickness of the first substrate is about 200 μm.

5. The display device of claim 4, wherein the first substrate does not overlap the bending area.

6. The display device of claim 2, wherein the second sub-substrate further comprises a third surface adjacent the second substrate, and a second side directed toward the bending area, and
wherein a second inclined angle formed by the third surface and the second side is an acute angle.

7. The display device of claim 6, wherein the first surface and the third surface are spaced apart from each other, and
wherein the second inclined angle increases as the first interval increases.

8. The display device of claim 7, wherein the second inclined angle is about 42° or more and about 88° or less.

9. The display device of claim 1, wherein the first sub-substrate comprises an edge surface extending from the second surface while overlapping an end of the first substrate, and
wherein an inclined angle formed by the second surface and the edge surface is an obtuse angle.

10. The display device of claim 1, further comprising a second side connecting the first surface with the first side,
wherein an undercut is formed between the second substrate and the second side.

11. The display device of claim 10, wherein an inclined angle formed by the first surface and the second side is an obtuse angle.

12. The display device of claim 10, wherein the first side and the second side extend from one another, and
wherein the first surface and the second surface extend from the first side and the second side.

13. The display device of claim 12, wherein an inclined angle formed by the first side and the second side is an acute angle.

14. The display device of claim 10, wherein the second substrate and the second side form a third inclined angle outside the first sub-substrate,
wherein the third inclined angle is inside the undercut, and is an acute angle.

15. The display device of claim 14, wherein the third inclined angle is about 14° or more and about 31° or less.

16. The display device of claim 10, wherein a length of the undercut in a direction parallel with the second substrate is greater than a height of the undercut in a direction substantially perpendicular to the second substrate.

17. A method for manufacturing a display device, the method comprising:
forming display cells on a second mother substrate that is on an upper surface of a first mother substrate;
forming a cutting line on the first mother substrate and the second mother substrate by irradiating a laser along a boundary of edges of the display cells;
forming a groove on a lower surface of the first mother substrate overlapping a bending area of the second mother substrate;
reducing a thickness of the first mother substrate by spraying an etchant onto the lower surface of the first mother substrate without a mask, and substantially concurrently removing a portion of the first mother substrate that overlaps the bending area of the second mother substrate along the groove; and
forming a second substrate and a first substrate by cutting the first mother substrate and the second mother substrate along the cutting line,
wherein the second substrate comprises a first sub-substrate and a second sub-substrate spaced apart from each other,
wherein the first sub-substrate further comprises a first side directed toward the second sub-substrate, a first inclined angle being formed by the first side and the first substrate, and
wherein the first inclined angle corresponds to a depth of the groove.

18. The method of claim 17, wherein the depth of the groove is about 0.4 times to about 0.9 times of the thickness of the first mother substrate.

19. The method of claim 18, wherein a size of the first inclined angle increases as the depth of the groove increases.

20. The method of claim 18, further comprising forming a second inclined angle outside the first sub-substrate by the first side and the first substrate,
wherein a size of the second inclined angle increases as the depth of the groove increases.
